(19) United States
(12) Patent Application Publication
(10) Pub. No.: US 2024/0034387 A1
(43) Pub. Date: Feb. 1, 2024

(54) ASSEMBLY COMPOSED OF A STEERING WHEEL HAVING AN ELECTRODE AND OF AN EVALUATION UNIT, THE EVALUATION UNIT BEING BETTER PROTECTED AGAINST SURGE VOLTAGE COUPLED IN FROM THE ELECTRODE AND BEING PROVIDED FOR CAPACITIVE TOUCH DETECTION, AND ASSOCIATED MOTOR VEHICLE

(71) Applicant: Preh GmbH, Bad Neustadt a.d. Saale (DE)

(72) Inventors: Manfred SCHNEIDER, Oberthulba (DE); Mario SCHMITT, Salz (DE)

(73) Assignee: Preh GmbH, Bad Neustadt a.d. Saale (DE)

(21) Appl. No.: 18/062,693

(22) PCT Filed: Apr. 19, 2022
(86) PCT No.: PCT/EP2022/060269

§ 371 Date: Dec. 7, 2022

(30) Foreign Application Priority Data
Apr. 21, 2021 (DE) 102021110300.2

(51) Int. Cl. B62D 1/04; B62D 1/06

(52) U.S. Cl. CPC B62D 1/046; B62D 1/065

(57) ABSTRACT

The present disclosure relates to an arrangement for a motor vehicle including a steering wheel, having an electrode, and evaluation electronics, which are to be protected against an electrical overvoltage and which are electrically conductively connected to the electrode for capacitive detection of a touch on the steering wheel, wherein the steering wheel has a steering wheel rim and an steering wheel core for fixing to a steering wheel shaft, wherein the steering wheel core is electrically conductively connected to a first ground connection via a first ohmic resistor, wherein the evaluation electronics are configured to apply an electrical measuring potential to the electrode to detect a touch on the steering wheel rim from; wherein the evaluation electronics are electrically conductively connected to a second ground connection; an electrically conductive connection provided between the electrode and the steering wheel core, which connection has an overvoltage discharge element.

The present disclosure relates to an arrangement comprising a steering wheel, having an electrode for capacitive touch detection, and evaluation electronics for detecting a touch on the steering wheel, in particular on the steering wheel rim, which are electrically conductively connected to the electrode. Steering wheels have progressed from simple input devices, for providing manual steering inputs on a steering assembly of a motor vehicle, to multi-functional input units, possibly with steering-control monitoring. Therefore, in addition to controlling the direction of a motor vehicle, it also serves to provide touch-based inputs through to gesture inputs for controlling other components of the motor vehicle. Moreover, it is increasingly designed to monitor the steering control of the motor vehicle driver, for example when driving the motor vehicle but in particular when switching to and from an autonomous driving state of the motor vehicle. The touch detection takes place regularly by establishing a measuring capacitance between an electrode and a first ground connection connected to the vehicle ground. The disadvantage with capacitive touch detection is that it is susceptible to overvoltages, i.e. voltages, in particular transient voltages, whereof the maximum voltage exceeds the value of the measuring potential used for touch detection by one or more orders of magnitude. This possibly results in disruption to the touch input or even damage to the evaluation electronics. It is therefore known to protect the evaluation electronics against overvoltages on its input side, which is connected to the electrode, by means of a protective circuit, wherein the protective circuit has at least one overvoltage discharge element provided in an electrical connection between the input side or electrode and the motor vehicle ground. This protective circuit ensures that the undesired overvoltage at the input side, which is electrically connected to the electrode, is discharged towards the motor vehicle ground. In this case, it is provided that, in the case of conventional protective circuits, the overvoltage reaches the associated second ground connection, via which the evaluation electronics are typically “grounded”, virtually without loss. However, since the first ground connection and the second ground connection diverge spatially and are separated from one another by a metallic body shell portion and/or frame portion which can be regarded as an electrical conductor, this leads to potential shifts between the first and second ground connection. These temporary potential shifts between the first and second ground connection may lead to unpredictable disruptions to the touch evaluation or touch detection by the evaluation electronics, such as false detection, which cannot be tolerated, in particular when monitoring the steering control of the motor vehicle driver or when switching from an autonomous driving state to a steering control by the motor vehicle driver or vice versa.

Against this background, there is a need for a solution in which an arrangement comprising a steering wheel, having an electrode for capacitive touch detection, and evaluation electronics for detecting a touch on the steering wheel, which are electrically conductively connected to the electrode, is better protected against coupled overvoltages on the electrode side. This object is achieved by an arrangement according to claim 1. An equally advantageous motor vehicle is the subject matter of the coordinate claim. Advantageous configurations are the subject matter of the dependent claims in each case. It should be noted that the features listed individually in the claims may be combined with one another in any technically meaningful manner and demonstrate further configurations of the present disclosure. The description, in particular in conjunction with the figures, additionally characterizes and specifies the present disclosure.

The present disclosure relates to an arrangement for a motor vehicle comprising a steering wheel, having an electrode, and evaluation electronics which are to be protected against an electrical overvoltage. The term motor vehicle in this case shall also include a software-supported simulation of a motor vehicle, in which the steering wheel forms an input device for realizing a virtual steering movement of a simulated motor vehicle. In general, the steering wheel is a component of a steering system of a motor vehicle, with which the motor vehicle driver, by turning the steering wheel, brings about a change in direction of the real or virtual motor vehicle in that one or more wheels of the motor vehicle change their steering position.

According to the present disclosure, the evaluation unit is conductively connected to one or more electrodes for capacitive detection of a touch on the steering wheel. According to the present disclosure, the steering wheel has a steering wheel rim and an electrically conductive steering wheel core for fixing to a steering wheel shaft on the motor vehicle. The steering wheel core is made of a metal or a metal alloy, for example, and forms a steering wheel hub for releasable fastening on a steering shaft of the motor vehicle. By way of example, a screw connection is provided between the steering shaft and the steering wheel hub. By way of example, the screw connection is covered by an impact absorber. By way of example, the steering wheel rim is designed in the form of a ring or, alternatively, as one or more ring segments. The steering wheel core extends, for example, from the steering wheel hub, via the steering wheel spoke to the steering wheel rim, so that the latter is fixed to the steering wheel hub by one or more steering wheel spokes, for example. By way of example, the electrode is integrated in the steering wheel rim.

According to the present disclosure, the steering wheel core is electrically conductively connected to a first ground connection via a first ohmic resistor.

According to the present disclosure, evaluation electronics, which, according to the present disclosure, are part of the arrangement, are designed to apply an electrical measuring potential to the electrode for touch detection in order to detect the touch on the steering wheel rim based on a change in a measuring capacitance formed between the electrode and the steering wheel core. According to the present disclosure, the evaluation electronics are furthermore electrically conductively connected to a second ground connection.

“Second connection” here means that this is not the same, i.e. not the first, connection. According to the present disclosure, the first and second ground connection are arranged spatially separate from one another and are electrically conductively connected via a ground path so that they preferably define or seek a common ground potential.

According to the present disclosure, a connection is provided between the electrode and the steering wheel core, which connection has an overvoltage discharge element, so that the connection is high-resistance when a measuring potential is applied at the electrode side, i.e. it has the effect of hindering or preferably blocking the current flow between the electrode and the steering wheel core, and low-resistance in the event of an overvoltage at the electrode side, i.e. it allows a preferably unhindered current flow between the two, in order to discharge the overvoltage from the electrode to the first ground connection via the steering wheel core in the latter case. By way of example, the low-resistance and the high-resistance state differ by more than one, preferably more than three, order(s) of magnitude (ohms). The overvoltage differs from the measuring potential, for example, by more than one, preferably more than three, order(s) of magnitude (volts).

As a result of the solution according to the present disclosure, the overvoltage is firstly conducted to the first ground connection via the first ohmic resistor in order to reach the evaluation unit via the ground path, whereby the overvoltage is reduced at least by the amount of the voltage drop at the first ohmic resistor, which means that a potential shift at the second ground connection due to the overvoltage does not occur, or is at least reduced, and an at least reduced potential, if any, resulting from the discharge of the overvoltage is applied to the evaluation electronics at their ground connection. Therefore, the touch detection of the evaluation electronics doesn't have to be interrupted in the event of an overvoltage and it is not disrupted. The capacitive touch detection function is based, for example, on the change in the electrical field in the environment in front of the electrode (active zone). The evaluation electronics have, for example, an RC oscillator circuit. The capacitance between the electrode and the electrical ground potential is measured as the measuring potential is applied. Instead of a measuring potential, it is also possible to provide a specifically provided counter electrode with an associated ground potential. As a result of a metallic or non-metallic material being brought closer to the electrode, in particular when touching the steering wheel rim, the capacitance increases and therefore influences the oscillation amplitude of the RC oscillator. This change causes a trigger stage downstream to “flip” and to change its output state, whereby a touch is positively detected. Therefore, a ground potential shift at the evaluation electronics due to overvoltage has a disastrous effect on the touch detection.

The overvoltage discharge element may be part of a multi-component electronic circuit, which establishes the electrical connection between the electrode and the steering wheel core. The above-mentioned overvoltage discharge element provided in the electrical connection between the electrode and the steering wheel core is preferably a diode, such as a transient absorption Zener diode or a transient voltage suppressor diode. The overvoltage discharge element is preferably arranged spatially closer to the evaluation electronics than the steering wheel core.

According to a preferred embodiment, the steering wheel core is furthermore connected to the second ground connection via a capacitor. This has the advantage that a potential applied to the steering wheel core is stabilized whilst the measuring capacitance is applied to the electrode or in the event of changes to the measuring capacitance, and electromagnetic interactions between the steering wheel core and the electrode when functioning as a measuring electrode, i.e. outside of the discharge of the overvoltage by the overvoltage discharge element, are minimized. A second ohmic resistor, whereof the ohmic resistance is greater than first ohmic resistance, is preferably connected in parallel with the capacitor in order to form an RC element. The second ohmic resistance is selected to be greater in order to ensure a greater discharge current across the steering wheel core and the first ground connection in the event of an overvoltage and discharge.

The first ohmic resistance is preferably in the range of 500Ω to 10 kΩ, preferably in the range of 800Ω to 1.2 kΩ.

The overvoltage is preferably conducted to the first ground connection via the steering wheel shaft. The first ohmic resistance is preferably formed substantially by a contact resistance in the region of the bearing of the steering wheel shaft. The first ohmic resistance can be defined, for example, as an average resistance over the entire adjustment path of the steering wheel from one steering stop to the opposite steering stop.

According to the present disclosure, the first ground connection and the second ground connection do not coincide spatially and are preferably arranged such that they observe a minimum spatial distance of 0.5 m from one another.

It is preferable if the first ground connection and the second ground connection are electrically conductively connected with potential equalization, i.e. with virtually zero resistance and thereby defining a common ground potential, or with preferably low resistance, i.e. having a one- or two-digit ohmic resistance at the most, via the ground path.

According to one configuration, at least one ground connection of the first and second ground connection is formed by a disconnectable electromechanical connecting device, such as a detachable force-fitting connecting device. Preferably, both the first and second ground connection are each formed by a disconnectable connecting device, such as a disconnectable force-fitting connecting device.

The electrode is preferably formed by a heating wire of a steering wheel heating device. By way of example, the heating operation is carried out by applying a pulse width modulated heating current to the heating wire, whilst the touch detection takes place in a dead time during the current application.

The evaluation electronics and the overvoltage discharge element are preferably arranged outside the steering wheel. By way of example, the evaluation electronics and the reader unit are arranged behind a steering column shroud or a screen of the dashboard or the center console of the motor vehicle.

The present disclosure furthermore relates to a motor vehicle having the arrangement in one of the previously described embodiments. In this case, the electrically conductive ground path between the first ground connection and the second ground connection is formed at least partially by a body shell and/or a frame of the motor vehicle.

The various embodiments are explained in more detail with the aid of the following figures. In this case, the figures should be understood to be merely exemplary and simply represent a preferred embodiment variant in each case.

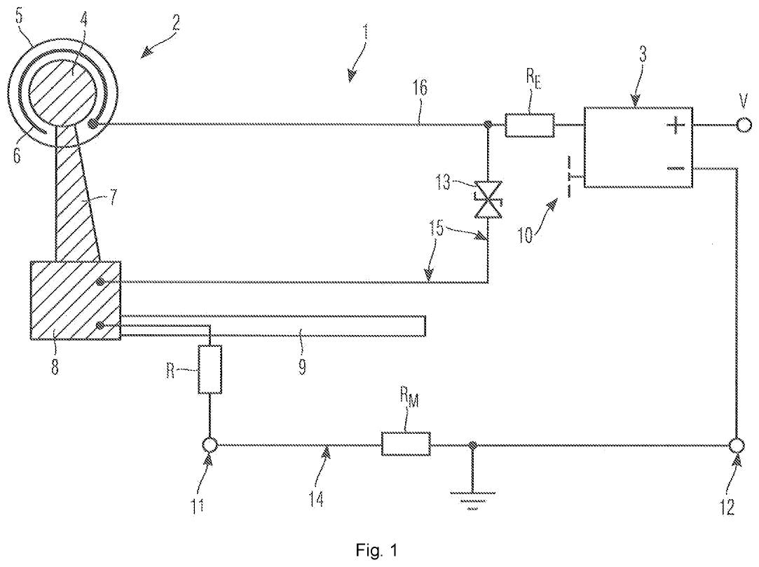

FIG. 1 shows a schematic illustration of a first embodiment of the arrangement;

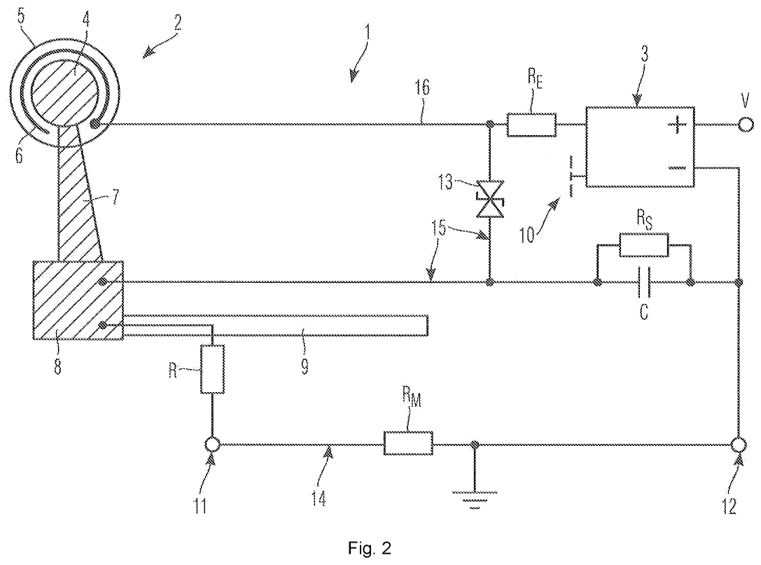

FIG. 2 shows a schematic illustration of a second embodiment of the arrangement;

FIG. 1 shows an embodiment of the arrangement 1. The arrangement 1 comprises a steering wheel 2 and evaluation electronics 3 arranged outside the steering wheel 2. The evaluation electronics 3 are protected against an overvoltage on the input side by an overvoltage discharge element 13, which is likewise arranged outside the steering wheel 2. The evaluation electronics 3 are designed for capacitive detection of a touch on the steering wheel 2 and the measuring input of the evaluation electronics 3 is therefore electrically conductively connected to an electrode 6 arranged on or in the steering wheel 2 via an input resistor RE.

The steering wheel 2 is only shown in part in the figures and not in detail. It has a conductive steering wheel core 4, which is preferably made of a metal or metal alloy and is fixed to a steering wheel shaft 9 of the motor vehicle (not illustrated). The steering wheel core 4 forms a steering wheel hub 8, which serves for fixing to the steering wheel shaft 9 and is electrically conductively connected to a first ground connection 11. The first ground connection 11 is formed by a disconnectable, force-fitting, electromechanical connecting device for establishing an electrical connection to the motor vehicle body shell or to the motor vehicle frame. The steering wheel core 4 extends over at least one steering wheel spoke 7 to a steering wheel rim 5, which is part of the steering wheel 2 and in which the steering wheel core 4 forms an inner skeleton, which stabilizes the steering wheel rim 5 and is surrounded by a plastic, leather or wood casing. The steering wheel rim 5 is designed for example in the form of a ring or at least in the form of a ring segment and forms the grip surface for a motor vehicle driver, whose touch is to be detected. In this casing of the steering wheel rim 5, an electrode 6 extending along the circumference of the steering wheel rim 5 is provided, which, apart from the connection 15 (described below) for the voltage discharge, is electrically insulated with respect to the steering wheel core 4. It should be clear to a person skilled in that art that, depending on the desired detection result, it is also possible to provide multiple electrodes, such as an electrode array, in order to be able to carry out spatially resolved touch detection on the touch surface of the steering wheel rim 5, for example.

In this embodiment, the electrode 6 is formed by a heating wire of a steering wheel heating system (not illustrated) which applies a pulse width modulated heating current to the heating wire, whilst the electrode 6 is available for touch detection in the dead time of this heating current. A measuring potential is applied to the electrode 6 by the evaluation electronics 3 via an electrically conductive connection 16. In addition to the electrical connection 16 to the electrode 6, the evaluation electronics 3 are furthermore connected to a supply voltage V, and, via their ground output, to a second ground connection 12, which is formed by a disconnectable, force-fitting, electromechanical connecting device for establishing an electrical connection to the motor vehicle body shell or to the motor vehicle frame.

The touch on the steering wheel rim 5 is detected by the evaluation electronics 3 on the basis of a change in a measuring capacitance formed between the electrode 6 and the steering wheel core 4, which is conductively connected to the first ground connection 11. The capacitive touch detection function is based, for example, on the change in the electrical field in the environment of the electrode 6, more precisely in the region of the surface of the steering wheel rim 5. The evaluation electronics 3 have, for example, an RC oscillator circuit. During the application of the measuring potential, the capacitance between the electrode 6 and the counter electrode, in this case the steering wheel core 4, to which the electrical ground potential is applied, is measured. As a result of a hand of the driver being brought closer to the electrode 6, in particular when touching the steering wheel rim 5, the capacitance increases and therefore influences the oscillation amplitude of the RC oscillator. This change causes a downstream trigger stage, which is part of the evaluation electronics 3, to “flip” and to change its output state, whereby a touch is positively detected and the detection result is output via a digital output 10, for example as part of a BUS system, such as a CAN bus. The sensitivity of the evaluation electronics 3 may generally be set by selecting the switching distance. A ground potential shift at the evaluation electronics due to overvoltage at the second ground connection therefore has a disastrous effect on the touch detection.

A connection 15 is provided between the electrode 6 and the steering wheel core 4, which connection has an overvoltage discharge element 13, so that the connection is high-resistance when a measuring potential is applied at the electrode side, i.e. it has the effect of hindering or preferably blocking a current flow, and low-resistance in the event of an overvoltage at the electrode side, i.e. it allows a preferably unhindered current flow, in order to conduct the overvoltage to the steering wheel core 4 in the latter case. By way of example, the low-resistance and the high-resistance state differ by more than one, preferably more than three, order(s) of magnitude (ohms). The overvoltage differs from the measuring potential, for example, by more than one, preferably more than three, order(s) of magnitude (volts). Since the steering wheel core 4 is furthermore electrically conductively connected to the first ground connection 11 via the first ohmic resistor R, the overvoltage is discharged at the first ground connection 11 and is reduced by the voltage drop at the first resistor R before it reaches the second ground connection 12 of the evaluation electronics 3 via the common ground line 14, which is realized for example by the motor vehicle body shell (not illustrated) or the motor vehicle frame (not illustrated). A further resistance R_{M}, which is produced by a distance of more than 0.5 m between the first ground connection 11 and the second ground connection 12 and may be in the range of 0.01 to 99.99 ohms, for example, has a supportive effect. The first ohmic resistance R is preferably in the range of 500Ω to 10 kΩ, preferably in the range of 800Ω to 1.2 kΩ. The overvoltage is conducted to the first ground connection 11 via the steering wheel shaft 9 here. The first ohmic resistance R is formed substantially by a contact resistance in the region of the bearing (not illustrated) of the steering wheel shaft 9. The first ohmic resistance can be defined, for example, as an average resistance over the entire adjustment path of the steering wheel 2 from one steering stop to the opposite steering stop.

As a result of the solution according to the disclosed embodiments, the overvoltage is firstly conducted to the first ground connection 11 via the first ohmic resistor R in order to reach the evaluation unit 3 via the ground path 14, whereby it is reduced at least by the amount of the voltage drop at the first ohmic resistor R, which means that a potential shift at the second ground connection 12 due to the overvoltage does not occur, or is at least reduced, and an at least reduced potential, if any, resulting from the discharge of the overvoltage is applied to the evaluation electronics 3 at their ground output.

FIG. 2 shows a second embodiment of the arrangement 1. The steering wheel core 4 here is furthermore connected to the second connection 12 via a capacitor C. This has the advantage that a potential applied to the steering wheel core 4 is stabilized whilst the measuring capacitance is applied to the electrode 6 or in the event of changes to the measuring capacitance, and electromagnetic interactions between the steering wheel core 4 and the electrode 6 when functioning as a measuring electrode, i.e. outside of the discharge of the overvoltage by the overvoltage discharge element, are minimized. A second ohmic resistor R_{S}, whereof the ohmic resistance is greater than the first ohmic resistance R, is preferably connected in parallel with the capacitor C in order to form an RC element. The second ohmic resistance R_{S} is selected to be greater in order to ensure a greater discharge current across the steering wheel core 4 and the first ground connection 11 in the event of an overvoltage and discharge.

What is claimed is:

1. An arrangement for a motor vehicle comprising a steering wheel, having an electrode, and evaluation electronics, which are to be protected against an electrical overvoltage and which are electrically conductively connected to the electrode for capacitive detection of a touch on the steering wheel, wherein the steering wheel has a steering wheel rim and an electrically conductive steering wheel core for fixing to a steering wheel shaft, wherein the steering wheel core is electrically conductively connected to a first ground connection via a first ohmic resistor, wherein the evaluation electronics are configured to apply an electrical measuring potential to the electrode for a touch detection, wherein the touch detection detects a touch on the steering wheel rim on the basis of a change in a measuring capacitance formed between the electrode and the steering wheel core; wherein the evaluation electronics are furthermore electrically conductively connected to a second ground connection, wherein the first ground connection and the second ground connection are arranged spatially separate from one another and are electrically conductively connected via a ground path;
a connection, which is provided between the electrode and the steering wheel core and wherein the connection has an overvoltage discharge element, wherein the connection is a high-resistance when a measuring potential is applied on the electrode side and wherein the connection is a low-resistance in an event of an overvoltage on the electrode side to discharge the overvoltage to the first ground connection via the steering wheel core.

2. The arrangement as claimed in claim 1, wherein the overvoltage discharge element is a diode.

3. The arrangement as claimed in claim 1, wherein the steering wheel core is furthermore connected to the second ground connection via a capacitor.

4. The arrangement as claimed in claim 3, wherein a second ohmic resistor is connected in parallel with the capacitor, wherein a resistance on the second ohmic resistor is greater than a resistance on the first ohmic resistor.

5. The arrangement as claimed in claim 1, wherein the resistance on the first ohmic resistor is in a range of 500Ω to 10 kΩ.

6. The arrangement as claimed in claim 1, wherein the overvoltage on the electrode side is conducted to the first ground connection via the steering wheel shaft.

7. The arrangement as claimed in claim 1, wherein the resistance on the first ohmic resistor is formed substantially by a contact resistance in a region of a bearing of the steering wheel shaft.

8. The arrangement as claimed in claim 1, wherein the first ground connection and the second ground connection are arranged to have a minimum spatial distance of 0.5 m from one another.

9. The arrangement as claimed in claim 8, wherein the first ground connection and the second ground connection are electrically conductively connected with a potential equalization, and thereby defining a common ground potential via the ground path.

10. The arrangement as claimed in claim 1, wherein the first ground connection and the second ground connection are each formed by a disconnectable electromechanical connecting device.

11. The arrangement as claimed in claim 1, wherein the electrode is formed by a heating wire of a steering wheel heating device.

12. The arrangement as claimed in claim 1, wherein the evaluation electronics and the overvoltage discharge element are arranged outside the steering wheel.

13. A motor vehicle, comprising:
an arrangement, wherein the arrangement further comprise:
a steering wheel, having an electrode, and evaluation electronics, which are to be protected against an electrical overvoltage and which are electrically conductively connected to the electrode for capacitive detection of a touch on the steering wheel, wherein the steering wheel has a steering wheel rim and an electrically conductive steering wheel core for fixing to a steering wheel shaft, wherein the steering wheel core is electrically conductively connected to a first ground connection via a first ohmic resistor, wherein the evaluation electronics are configured to apply an electrical measuring potential to the electrode for a touch detection, wherein the touch detection detects a touch on the steering wheel rim on the basis of a change in a measuring capacitance formed between the electrode and the steering wheel core; wherein the evaluation electronics are furthermore electrically conductively connected to a second ground connection, wherein the first ground connection and the second ground connection are arranged spatially separate from one another and are electrically conductively connected via a ground path;
a connection, which is provided between the electrode and the steering wheel core and wherein the connection has an overvoltage discharge element, wherein the connection is a high-resistance when a measuring potential is applied on the electrode side and wherein the connection is a low-resistance in an event of an overvoltage on the electrode side to discharge the overvoltage to the first ground connection via the steering wheel core,
wherein a conductive ground path between the first ground connection and the second ground connection is formed at least partially by at least one of:
a body shell and a frame of the motor vehicle

14. The arrangement as claimed in claim 1, wherein the overvoltage discharge element is any one of: a transient absorption Zener diode and a transient voltage suppressor diode.

15. The arrangement as claimed in claim 8, wherein the first ground connection and the second ground connection are electrically conductively connected with a low resistance (R_{M}) via the ground path.
